(19) United States
(12) Patent Application Publication
(10) Pub. No.: US 2014/0290058 A1
(43) Pub. Date: Oct. 2, 2014

(54) METHOD OF MANUFACTURING A CIRCUIT BOARD

(71) Applicant: Tyco Electronics Corporation, Berwyn, PA (US)

(72) Inventors: Charles Randall Malstrom, Lebanon, PA (US); Marjorie Kay Myers, Mount Wolf, PA (US); John Patton Geiger, Waynesboro, PA (US)

(21) Appl. No.: 14/301,011

(22) Filed: Jun. 10, 2014

Related U.S. Application Data
(62) Division of application No. 13/215,912, filed on Aug. 23, 2011.

(51) Int. Cl. H05K 3/04

(52) U.S. Cl. CPC H05K 3/043
USPC 29/846

(57) ABSTRACT

A method of manufacturing a circuit board includes providing a metal substrate and applying a dielectric layer to the metal substrate and sacrificial bumps on the dielectric layer. The method also includes printing a conductive seed layer on the dielectric layer and the sacrificial bumps and plating a conductive circuit layer onto the conductive seed layer. The method includes removing sections of the conductive seed layer and sections of the conductive circuit layer during a circuit common removal process

### CROSS REFERENCE TO RELATED APPLICATIONS

This application is a continuation application of U.S. patent application Ser. No. 13/215,912 filed Aug. 23, 2011, titled CIRCUIT BOARD, the subject matter of which is herein incorporated by reference in its entirety.

### BACKGROUND OF THE INVENTION

The subject matter herein relates generally to circuit boards and methods of manufacturing circuit boards.

Currently, within the solid state lighting market, light emitting diodes (LEDs) are mounted on metal clad circuit boards. The metal clad circuit boards are useful in high power LED solutions for adequate heat spreading or heat sinking of the LEDs. Metal clad circuit boards may be used in other high power/high heat applications as well.

Metal clad circuit boards typically include a base material, such as an aluminum sheet, that has an electrically insulative, but somewhat thermally conductive layer to isolate the base aluminum from copper traces which are on top of the insulative layer. The metal clad circuit boards are manufactured by a subtractive process, much like a traditional printed circuit board made from a glass epoxy material, such as an FR4 circuit board. A copper sheet is applied to the insulative layer, and the copper sheet is etched away to create the necessary circuit traces. Such a process is referred to as a subtractive process to remove the copper from the copper sheet applied to the circuit board substrate via etching or machining to achieve the circuit trace geometry. Typically, a solder mask is placed on top of the traces.

Circuit boards manufactured by a subtractive process are not without disadvantages. For instance, every time a new geometry or circuit is required, a photo-resist etch plate needs to be created. This requires time and money investment before the circuit geometry can be made.

A need remains for a metal clad circuit board that can be manufactured in a cost effective and reliable manner. A need remains for a metal clad circuit board that has effective heat dissipation.

### BRIEF DESCRIPTION OF THE INVENTION

In one embodiment, a circuit board is provided having a dielectric layer and sacrificial bumps on the dielectric layer in predetermined circuit common areas. A conductive seed layer is printed on the dielectric layer and the sacrificial bumps. A conductive circuit layer is plated onto the conductive seed layer. Sections of the conductive circuit layer and the conductive seed layer in the circuit common areas are removed after plating. Optionally, the circuit board may include a metal substrate, with the dielectric layer applied on the metal substrate.

Optionally, the sacrificial bumps are elevated above an outer surface of the dielectric layer raising the conductive seed layer and the conductive circuit layer in the circuit common areas. The conductive seed layer and the conductive circuit layer transition from the dielectric layer to the sacrificial bumps such that the conductive seed layer and the conductive circuit layer are non-planar along the circuit board. Optionally, the sacrificial bumps comprise a dielectric material applied to the dielectric layer in circuit common areas. Portions of the sacrificial bumps may be removed with removal of the sections of the conductive circuit layer and the conductive seed layer in the circuit common areas. The conductive seed layer and conductive circuit layer define conductive traces, sections of the conductive traces in the circuit common areas may be removed to create an electrical discontinuity at the circuit common areas. The discontinuity is defined between remaining sections of the conductive circuit layer and the conductive seed layer that remain after the sections of the conductive circuit layer and the conductive seed layer are removed. At least a portion of the sacrificial bump may remain intact between the discontinuity and the dielectric layer in the circuit common areas.

In another embodiment, a circuit board is provided having a metal substrate. A dielectric layer is applied to the metal substrate and has an outer surface. Sacrificial bumps are provided on the dielectric layer in predetermined circuit common areas that have outer surfaces elevated above the outer surface of the dielectric layer in the area surrounding the sacrificial bump. A conductive seed layer is printed on the outer surface of the dielectric layer and is printed on the outer layer of the sacrificial bumps. A conductive circuit layer is plated onto the conductive seed layer. The conductive circuit layer and the conductive seed layer on the outer surfaces of the sacrificial bumps are elevated above the conductive circuit layer and the conductive seed layer on the outer surface of the dielectric layer. Sections of the conductive circuit layer and the conductive seed layer on the sacrificial bumps are configured to be removed.

In a further embodiment, a method of manufacturing a circuit board is provided. The method includes providing a metal substrate and applying a dielectric layer to the metal substrate and sacrificial bumps on the dielectric layer. The method also includes printing a conductive seed layer on the dielectric layer and the sacrificial bumps and plating a conductive circuit layer onto the conductive seed layer. The method includes removing sections of the conductive seed layer and sections of the conductive circuit layer during a circuit common removal process.

### BRIEF DESCRIPTION OF THE DRAWINGS

FIG. 1 is a perspective view of an LED assembly formed in accordance with an exemplary embodiment.

FIG. 2 is a cross-sectional view of a metal clad circuit board formed in accordance with an exemplary embodiment for the LED assembly shown in FIG. 1.

FIG. 3 is a cross-sectional view of the metal clad circuit board.

FIG. 4 is another cross-sectional view of the metal clad circuit board.

FIG. 5 is a top view of the metal clad circuit board prior to adding conductive traces to the metal clad circuit board.

FIG. 6 is a top view of the metal clad circuit board after adding conductive traces to the metal clad circuit board.

FIG. 7 is a top view of the metal clad circuit board after a circuit common removal process.

FIG. 8 is a flow chart showing a method of manufacturer of a metal clad circuit board.

### DETAILED DESCRIPTION OF THE INVENTION

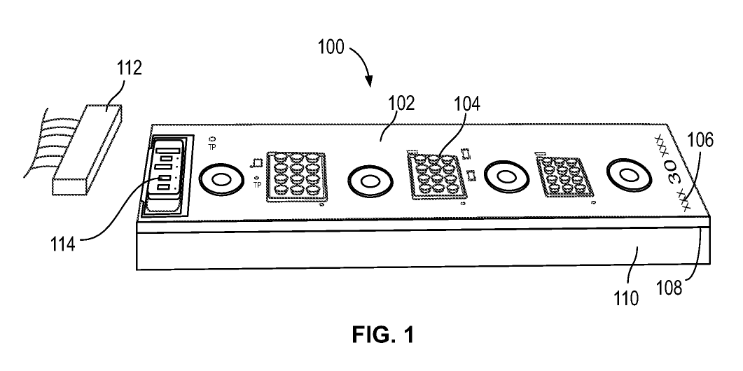

FIG. 1 is a perspective view of an LED assembly 100 formed in accordance with an exemplary embodiment. The LED assembly 100 includes a metal clad circuit board 102 having a plurality of LEDs 104 mounted to a top surface 106 of the metal clad circuit board 102. A bottom surface 108 of the metal clad circuit board 102 is mounted to a heat sink 110. The metal clad circuit board 102 may be used in other applications other than in an LED assembly 100. For example, the metal clad circuit board 102 may be used as part of a power device, an antenna, or other applications. Additionally, the embodiments and methods described herein of manufacturing a circuit board may be used on other types of circuit board other than metal clad circuit boards, such as circuit boards having a glass epoxy substrate or a flexible film substrate. Such circuit boards do not include a metal substrate.

A power connector 112 is configured to be electrically connected to the LED assembly 100 to supply power to the LED assembly 100. The metal clad circuit board 102 includes a plurality of power pads 114 proximate to an edge of the metal clad circuit board 102. The power connector 112 is coupled to the metal clad circuit board 102 such that the power connector 112 engages the power pads 114. Power is supplied to the metal clad circuit board 102 via the power pads 114.

The metal clad circuit board 102 includes a metal substrate that provides heat transfer to the heat sink 110 to cool the components mounted to the metal clad circuit board 102, such as the LEDs 104. The metal substrate of the metal clad circuit board 102 provides better thermal transfer than other types of circuit boards, such as circuit boards manufactured from glass epoxy or FR4 materials. The metal substrate of the metal clad circuit board 102 provides a mechanically robust substrate that is not as fragile as other types of circuit boards. The metal clad circuit board 102 provides low operating temperatures for the LEDs 104 and has increased thermal efficiency for dissipating heat from the LEDs 104. The metal clad circuit board 102 has high durability and may have a reduced size by limiting the need for an additional heat transfer layer.

The metal clad circuit board 102 may have a variety of shapes of sizes depending on the particular application. In the illustrated embodiment, the metal clad circuit board 102 is elongated and rectangular in shape. The LEDs 104 are arranged in line along the top surface 106. Alternative configurations of the LEDs 104 are possible in alternative embodiments. Any number of LEDs 104 may be provided on the top surface 106 depending on the particular application and lighting effect desired. The metal clad circuit board 102 may be generally circular in shape in an alternative embodiment. The LED assembly 100 may include other electronic components on the top surface 106 of the metal clad circuit board 102. For example, the LED assembly 100 may include other electronic components, such as capacitors, resistors, sensors, and the like on the top surface 106.

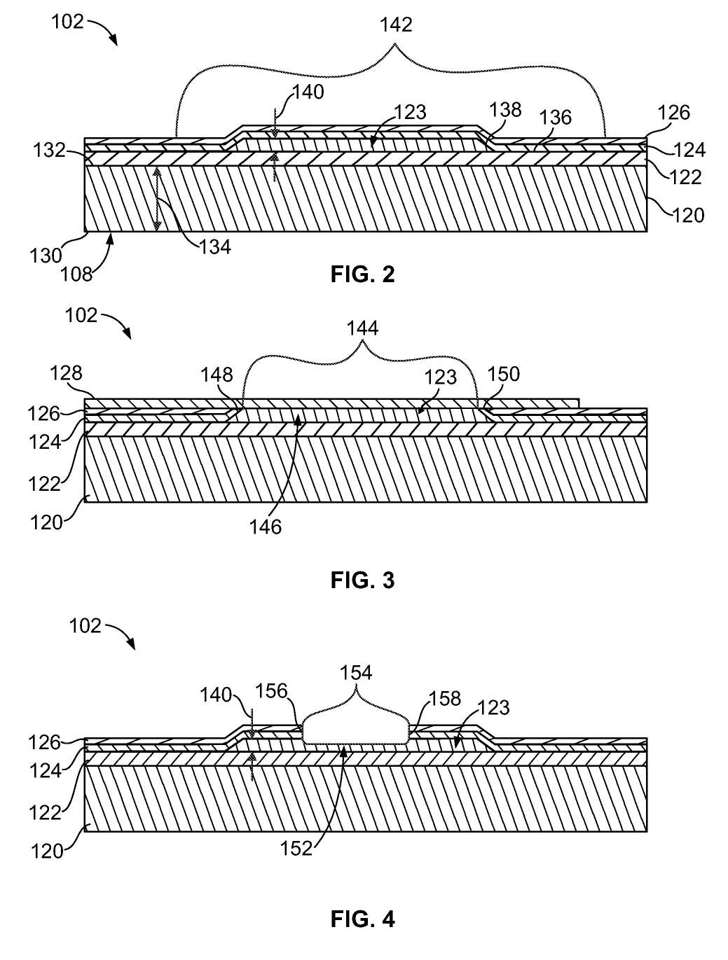

FIG. 2 is a cross-sectional view of the metal clad circuit board 102 formed in accordance with an exemplary embodiment. The metal clad circuit board 102 includes a metal substrate 120, a dielectric layer 122 applied to the metal substrate 120, a sacrificial bump 123 on the dielectric layer 122, a conductive seed layer 124 printed on the dielectric layer 122 and the sacrificial bump 123, a conductive circuit layer 126 plated onto the conductive seed layer 124, and a solder mask layer 128 (shown in FIG. 3) applied over the conductive circuit layer 126. The different layers are defined as having different characteristics. The different layers may be formed from different materials. The different layers may be deposited on the other layer. The metal clad circuit board 102 may have other layers in alternative embodiments, which may be interspersed between the layers identified above. A layer can be said to be deposited on, applied on, applied to, applied over and the like with respect to another layer, while having other layers interspersed therebetween. A layer is said to be directly deposited on, directly applied on, directly applied to, directly over and the like with respect to another layer when such layer directly engages and no other layer is interspersed therebetween. The metal clad circuit board 102 may be manufactured with fewer layers in alternative embodiments.

The metal substrate 120 is provided at the bottom surface 108 of the metal clad circuit board 102. The metal substrate 120 extends between a first surface 130 and a second surface 132. The first surface 130 is configured to be mounted to the heat sink 110 (shown in FIG. 1). Optionally, a thermal interface material (not shown) may be applied to the first surface 130 for interfacing with the heat sink 110. The dielectric layer 122 is applied to the second surface 132. The metal substrate 120 has a thickness 134 measured between the first and second surfaces 130, 132.

The metal substrate 120 is fabricated from a material having a high thermal efficiency, such as an aluminum material, a copper material, and the like. The metal substrate 120 efficiently transfers heat from the components mounted to the metal clad circuit board 102, such as the LEDs 104 (shown in FIG. 1). The thickness 134 may be at least half the overall thickness of the metal clad circuit board 102 measured between the top surface 106 and the bottom surface 108. Having a thick metal substrate 120 provides rigidity and robustness to the metal clad circuit board 102.

The dielectric layer 122 is positioned between the metal substrate 120 and the conductive seed layer 124. The dielectric layer 122 electrically isolates the metal substrate 120 from the conductive seed layer 124. The dielectric layer 122 has a low thermal resistance so that effective thermal transfer can occur to the metal substrate 120. The thickness of the dielectric layer 122 as well as the type of material used for the dielectric layer 122 may affect the thermal conductivity or thermal resistivity properties of the dielectric layer 122. The dielectric layer 122 is relatively thin to allow effective thermal transfer through the dielectric layer 122 to the metal substrate 120.

The dielectric layer 122 needs to maintain adequate dielectric properties to maintain electrical isolation between the metal substrate 120 and the conductive seed layer 124 and/or the conductive circuit layer 126. For example, the dielectric layer 122 may need to be rated to withstand a predetermined voltage level, such as 2500 volts. The thickness of the dielectric layer 122, as well as the type of material used for the dielectric layer 122, may affect the dielectric properties and effectiveness of the dielectric layer 122. Different types of dielectric materials may be used in various embodiments. In an exemplary embodiment, the dielectric layer 122 is manufactured from polymer particles. Optionally, the dielectric layer 122 may include fillers or other particles mixed in with the polymers to change properties of the dielectric layer 122, such as the thermal efficiency of the dielectric layer 122. For example, particles such as alumina or boron nitride particles may be added to the polymer particles to make the dielectric layer 122 more thermally conductive. Other types of fillers may be added to the mixture to change other characteristics of the dielectric layer 122.

The dielectric layer 122 may be applied to the metal substrate 120 using different processes. In an exemplary embodiment, the dielectric layer 122 is powdered coated to the metal substrate 120. The dielectric layer 122 includes fine powder particles composed of a mixture of polymer and fillers that may be compression molded onto the metal substrate 120 or using other coating techniques, such as being electrostatically powder coated, reflowed or by using other techniques. Different types of fillers may be used to change the characteristics of the dielectric layer 122.

In an alternative embodiment, the dielectric layer 122 may be an epoxy applied to the metal substrate 120. For example, the dielectric layer 122 may include a liquid suspension having a mixture of polymers, fillers and solvent that is spread onto a silicone coated polyester film, which is partially cured to an intermediate stage then transferred to the metal substrate 120. The mixture is then compression molded to the metal substrate 120. The liquid suspension, when cured, may have a uniform surface for good contact with the metal substrate 120. In another alternative embodiment, the dielectric layer 122 may include a film, such as a polyester film, that is applied to the metal substrate 120.

The sacrificial bump 123 is provided on the dielectric layer 122. The sacrificial bump 123 is provided in a circuit common area of the metal clad circuit board 102. In an exemplary embodiment, at least portions of the sacrificial bump 123 are later removed to remove shorts created in the circuit common areas that are there for the purpose of creating the conductive circuit layer 126. In an exemplary embodiment, the sacrificial bump 123 is separately provided from, and applied to, the dielectric layer 122. For example, the sacrificial bump 123 is applied after the dielectric layer 122 is bonded and cured to the metal substrate 120. The sacrificial bump 123 may be manufactured from a material that is different than the material of the dielectric layer 122. In an exemplary embodiment, the sacrificial bump 123 is manufactured from a dielectric material, such as a polymer material. The sacrificial bump 123 may be an epoxy material. Alternatively, the sacrificial bump 123 may be manufactured from another suitable material.

The sacrificial bump 123 is arranged within the circuit common area of the metal clad circuit board 102. Any number of sacrificial bumps 123 may be used on the metal clad circuit board 102, depending on the number of circuit common areas. The sacrificial bump 123 is elevated above an outer surface 136 of the dielectric layer 122. In an exemplary embodiment, the sacrificial bump 123 includes a curved outer surface 138. The outer surface 138 may be plateaued and have a flat top. Alternatively, the outer surface 138 may have a mound shape that is domed. The sacrificial bump 123 has a thickness 140 measured at the thickest part of the sacrificial bump 123, which may be near or at the center of the sacrificial bump 123. The thickness 140 provides additional thickness to the dielectric layer 122. A portion of the sacrificial bump 123 may be removed during a removal process, as described in further detail below. The sacrificial bump 123 is removed without removing any of the dielectric layer 122. The sacrificial bump 123 is sacrificed during the removal process to maintain the integrity of the dielectric layer 122.

In an exemplary embodiment, the sacrificial bump 123 is applied to the dielectric layer 122 by printing the material of the sacrificial bump 123 onto the dielectric layer 122, such as by pad printing, ink jet printing or silk screen printing. Alternatively, the sacrificial bump 123 may be applied by another process, such as by applying a drop or bead of material on the dielectric layer 122 using a syringe or other device.

The conductive seed layer 124 is applied the dielectric layer 122 and the sacrificial bump 123. For example, the conductive seed layer 124 is provided on the outer surface 136 of the dielectric layer 122 and the outer surface 138 of the sacrificial bump 123. The conductive seed layer 124 transitions from the planar surface of the dielectric layer 122 to the radiused or curved surface of the sacrificial bump 123. The portion of the conductive seed layer 124 on the sacrificial bump 123 is non-planar with the other portions of the conductive seed layer 124 on the dielectric layer 122. The portion of the conductive seed layer 124 on the sacrificial bump 123 is elevated above the other portions of the conductive seed layer 124 on the dielectric layer 122. The sacrificial bump 123 is provided between the conductive seed layer 124 and the dielectric layer 122 in the circuit common area.

The conductive seed layer 124 may include conductive ink that is printed onto the dielectric layer 122 and the sacrificial bump 123. Optionally, the conductive ink may be a silver ink. The conductive seed layer 124 may include additives, such as adhesion promoters. In an exemplary embodiment, the conductive ink is printed onto the dielectric layer 122 and the sacrificial bump 123 using a printing process, such as inkjet printing, pad printing or screen printing. Other processes may be used to apply the conductive ink onto the dielectric layer 122 and the sacrificial bump 123 in alternative embodiments.

The conductive seed layer 124 forms base conductive traces on the metal clad circuit board 102. Once the base conductive traces have been applied, the base conductive traces are over-plated with copper or another conductive material, to create the conductive circuit layer 126. The copper may be deposited quickly. The thickness of the conductive circuit layer 126 may be controlled to achieve a suitable current carrying capacity. The base conductive traces may be over-plated with other elements, such as tin to provide environmental protection and a solderable surface. The tin may be applied during a plating process to create part of the conductive circuit layer 126. The conductive seed layer 124 and the conductive circuit layer 126 together define conductive traces of the metal clad circuit board 102.

In an exemplary embodiment, the conductive circuit layer 126 is electroplated to the base conductive traces defined by the conductive seed layer 124 to form the conductive circuit layer 126. The conductive circuit layer 126 has a much higher current carrying capability than the conductive seed layer 124, which increases the current carrying capability of the metal clad circuit board 102. For example, the conductive seed layer 124 has enough current carrying capability to allow the electroplating of the conductive circuit layer 126. The conductive circuit layer 126, which is electroplated to the conductive seed layer 124, has enough current carrying capability for the particular application, such as powering the LEDs 104 (shown in FIG. 1).

In an exemplary embodiment, to achieve electroplating, all of the conductive traces need to be commoned as part of one circuit. The conductive seed layer 124 defines such a circuit, which is then electroplated to form the conductive circuit layer 126. Predetermined areas, referred to as circuit commons 142 in the circuit common areas, need to be removed after the electroplating process, to create discontinuities 144 (shown in FIG. 3) in the conductive traces of the metal clad circuit board 102. The discontinuities allow separate circuits to be defined on the metal clad circuit board 102. The circuit commons may be removed by a milling process, a laser removal process, a chemical removal process, an electro-machining process, and the like.

FIG. 3 is a cross-sectional view of the metal clad circuit board 102 after a circuit common removal process. During removal of each circuit common 142 (shown in FIG. 2), a portion of the sacrificial bump 123 underlying the circuit common 142 is removed. In an exemplary embodiment, less than the entire sacrificial bump 123 is removed such that a remaining portion 146 of the sacrificial bump 123 remains between the discontinuity 144 and the dielectric layer 122.

In an exemplary embodiment, the conductive traces forming the circuit common 142 is removed by a milling process in which the conductive seed layer 124 and the conductive circuit layer 126 at the sacrificial bump 123 are removed, such as by using a planar or grinder. A portion of the sacrificial bump 123 may also be removed during the milling process. The discontinuity 144 extends between a first trace end 148 and a second trace end 150. The dielectric layer 122 remains intact and untouched during the milling process. The thickness 140 (shown in FIG. 2) of the sacrificial bump 123 may be selected based on the removal method. For example, the thickness 140 of the sacrificial bump 123 may be greater than a combined thickness of the conductive seed layer 124 and the conductive circuit layer 126 such that the circuit common 142 may be removed without removing other portions of the conductive seed layer 124 and the conductive circuit layer 126. The thickness 140 may depend on a tolerance of the milling machine to ensure that the dielectric layer 122, the conductive seed layer 124 and the conductive circuit layer 126, which is outside of the circuit common area and the forms the functional circuit, are not damaged.

The solder mask layer 128 is selectively applied over the conductive circuit layer 126 to protect the conductive circuit layer 126, such as from corrosion. Portions of the conductive circuit layer 126 are exposed through the solder mask layer 128 to allow for soldering of components to the conductive circuit layer 126. In an exemplary embodiment, the solder mask layer 128 is applied to the metal clad circuit board 102 using a printing process, such as a pad printing process. Alternatively, the solder mask layer 128 may be applied using other processes, such as an inkjet printing process or other processes for applying the solder mask layer 128. The solder mask layer 128 is applied after the circuit common removal process. Optionally, the metal clad circuit board 102 may be provided without the solder mask layer 128.

FIG. 4 is a cross-sectional view of the metal clad circuit board 102 after an alternative circuit common removal process. During removal of each circuit common 142 (shown in FIG. 2), a portion of the sacrificial bump 123 underlying the circuit common 142 is removed. In an exemplary embodiment, less than the entire sacrificial bump 123 is removed such that a remaining portion 152 of the sacrificial bump 123 remains between a discontinuity 154 of the conductive trace and the dielectric layer 122.

In an exemplary embodiment, the conductive traces forming the circuit common 142 is removed by a laser cutting process in which the conductive seed layer 124 and the conductive circuit layer 126 at the sacrificial bump 123 are removed. A portion of the sacrificial bump 123 may also be removed during the laser cutting process. The discontinuity 154 extends between a first trace end 156 and a second trace end 158. The dielectric layer 122 remains substantially intact and untouched during the cutting or removal process such that the dielectric layer 122 remains functional. The thickness 140 of the sacrificial bump 123 may be selected based on the removal method. For example, the thickness 140 of the sacrificial bump 123 may be thick enough such that the laser is able to cut entirely through the circuit common 142 and partially into the sacrificial bump 123 below the circuit common 142 without cutting into the dielectric layer 122. The thickness 140 may depend on a tolerance of the laser cutting machine to ensure that the dielectric layer 122 is not damaged.

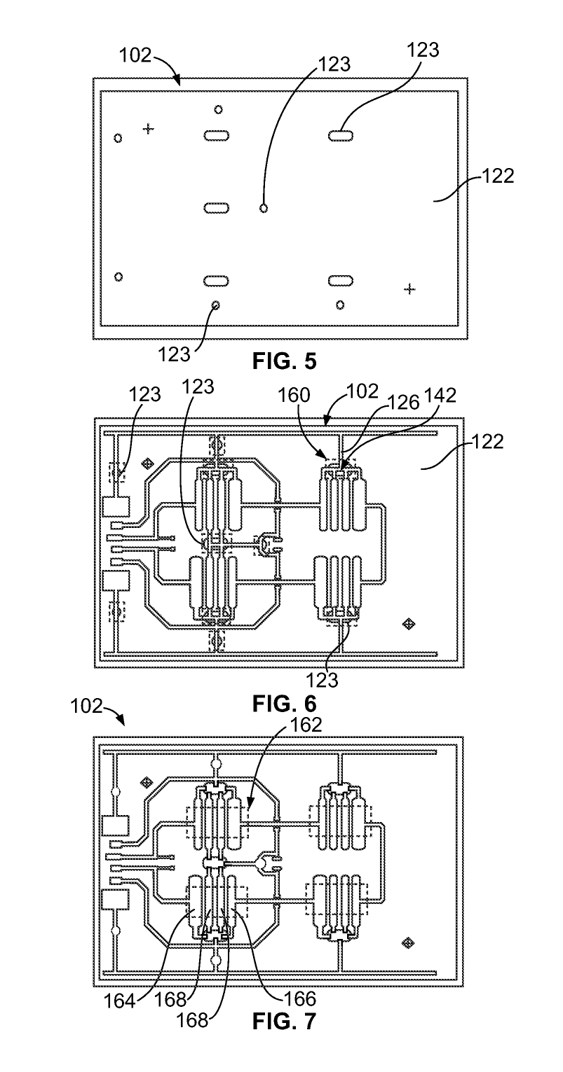

FIG. 5 is a top view of the metal clad circuit board 102 prior to adding conductive traces to the metal clad circuit board 102. The sacrificial bumps 123 are added to the dielectric layer 122 in predetermined areas based on the end circuit configuration desired. The sacrificial bumps 123 extend from the dielectric layer 122 and are elevated from the dielectric layer 122. The sacrificial bumps 123 may have any size or shape depending on the particular application and end circuit configuration. Any number of sacrificial bumps 123 may be provided depending on the end circuit configuration.

FIG. 6 is a top view of the metal clad circuit board 102 after adding the conductive traces to the metal clad circuit board 102. The conductive traces are added by applying the conductive seed layer 124 (shown in FIG. 2) and the conductive circuit layer 126, which together define the conductive traces. The arrangement of the conductive traces is based on the particular application and the number and positioning of the electrical components, such as the LEDs 104 (shown in FIG. 1) on the metal clad circuit board 102.

The conductive traces have circuit commons 142 in circuit common areas 160. The circuit commons 142 are the portions of the conductive traces that electrically common all of the conductive traces so that the conductive circuit layer 126 can be electroplated to the conductive seed layer 124. The circuit commons 142 need to be removed to electrically isolate the various circuits of the metal clad circuit board 102. The sacrificial bumps 123 are arranged in the circuit common areas 160 and the circuit commons 142 are routed along the sacrificial bumps 123. In an exemplary embodiment, the sacrificial bumps 123 are flexible and may be compressed or deflected during the printing process, such as during a pad printing process in which a printing pad is pressed onto the metal clad circuit board 102 to deposit the conductive ink of the conductive seed layer 124. The printing process conforms to the topography to apply the seed layer across the transition from the flat dielectric layer 122 to the sacrificial bumps 123. Such deflection ensures adequate contact with the printing pad and depositing of the conductive ink on the sacrificial bump 123. During the circuit common removal process, sections of the circuit commons 142 (e.g. sections of the conductive seed layer 124 and sections of the conductive circuit layer 126) in the circuit common areas 160 are removed, leaving the conductive circuit layer 126 that forms the functional circuit behind.

FIG. 7 is a top view of the metal clad circuit board 102 after a circuit common removal process. After the circuit common removal process, at least some of the conductive traces are separated from one another. For example, in a component mounting area 162, a cathode 164, an anode 166 and a pair of heat sinks 168 are provided and separated from one another. Prior to the circuit common removal process, the cathode 164, the anode 166 and the heat sinks 168 are all part of a common circuit. After the circuit common removal process, the cathode 164, the anode 166 and the heat sinks 168 are all electrically isolated from one another. Multiple component mounting areas 162 may be provided. The component mounting areas 162 may be arranged in series or in parallel depending on the circuit configuration. The component mounting areas 162 may include other types of pads in alternative embodiments.

One of the LEDs 104 (shown in FIG. 4) may be mounted to the metal clad circuit board 102 at the component mounting area 162. The LED 104 includes a plurality of mounting pads (not shown) that are configured to be soldered to the cathode 164 and the anode 166 for powering the LED 104 and to the heat sinks 168 for dissipating heat from the LED 104. After the solder mask process, in which the solder mask layer 128 (shown in FIG. 3) is applied to the metal clad circuit board 102, the cathode 164, the anode 166 and the heat sinks 168 remain exposed so that the LED can be soldered to the cathode 164, the anode 166 and the heat sinks 168.

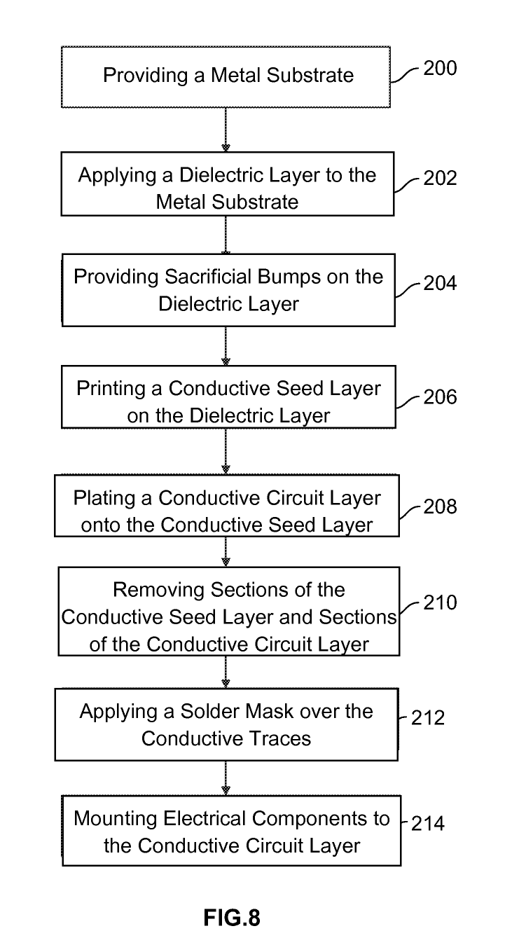

FIG. 8 is flow chart showing a method of manufacturing a metal clad circuit board, such as the metal clad circuit board 102 shown in FIGS. 1-2. The method includes providing 200 a substrate. The substrate may be a metal substrate or may be another type of substrate. The metal substrate may be cut from an aluminum panel to a predetermined size. The substrate may be manufactured in a different way and/or from a different material.

The method includes applying 202 a dielectric layer to the metal substrate. The dielectric layer may be applied to the metal substrate by powder coating a powder mixture to a surface of the metal substrate. The powder mixture may be compression molded to the metal substrate or applied by another coating technique such as powder coating, reflowing or other techniques. In an exemplary embodiment, the metal substrate may be held within a device having a base with a silicone coated polyester sheet between the base and the metal substrate. The loose powder mixture may be poured onto the metal substrate and another silicone coated polyester film may be placed over the powder mixture. The powder mixture may be applied using an electrostatic spray or another means to apply the dielectric material to the substrate. A steel plate may be pressed onto the assembly using a high force to apply the dielectric layer to the metal substrate. The sample may be hot pressed to the metal substrate using heat and pressure to bond the dielectric layer the metal substrate. The films may be pulled away from the pressed sample after the dielectric layer is applied to the metal substrate. Other types of devices may be used to form the sample. For example, a draw down coater or a slot die coater may be used to create the sample. Other types of devices, other than coaters, may be used to create a sample.

In an alternative embodiment, the dielectric layer may be formed by forming a liquid suspension coating that is cured and applied to the metal substrate. For example, a polyester film may be placed on the bed of a doctor blade coater. A bead of epoxy fabricated from polymers, fillers and solvent is spread on the film in front of the blade. The epoxy is spread across the film by the blade to create a sample. The sample is cured in an oven to an intermediate or partial curing stage. The intermediately cured sample may be cut to size and placed in contact with the metal substrate. The sample may be hot pressed to the metal substrate using heat and pressure to bond the dielectric layer the metal substrate.

The method includes providing 204 sacrificial bumps on the dielectric layer. The sacrificial bumps are provided in circuit common areas, which are located in various locations on the metal clad circuit board depending on the particular circuit configuration. The sacrificial bumps may be applied by a printing process, such as a pad printing process, an ink jet printing process, a screen printing process and the like. Alternatively, the sacrificial bumps may be applied using an alternative method, such as applying a drop or bead of material on the dielectric layer using a syringe or other depositing device.

In other alternative embodiments, the sacrificial bumps may be provided simultaneously with, as part of the same process of applying 202 the dielectric layer. For example, the dielectric layer and the sacrificial bumps may be formed as part of a common mold that is applied to the metal substrate at the same time. The dielectric layer and the sacrificial bumps may be pre-molded and applied during a hot pressing process. Alternatively, the dielectric layer and the sacrificial bumps may be co-formed during a common pressing operation on the metal substrate, such as by spreading a powder mixture on the metal substrate and pressing the mixture onto the metal substrate to form the dielectric layer and the sacrificial bumps.

The method includes printing 206 a conductive seed layer on the dielectric layer. The conductive seed layer includes conductive ink that is printed onto the dielectric layer. The conductive ink may be printed using an inkjet printer in one embodiment. In another embodiment, the conductive ink may be printed onto the dielectric layer using a pad printing process or a screen printing process. The conductive seed layer defines base conductive traces on the dielectric layer. The conductive seed layer may be applied to the dielectric layer by other processes other than printing in alternative embodiments.

In an exemplary embodiment, to enhance the conductive properties of the base conductive traces, a conductive circuit layer may be plated 208 onto the conductive seed layer. In an exemplary embodiment, the conductive circuit layer is plated onto the conductive seed layer using an electroplating process. Other plating processes may be used in alternative embodiments to apply the conductive circuit layer to the conductive seed layer. In other alternative embodiments, the conductive circuit layer may be added to the dielectric layer without the use of printing the conductive seed layer.

The conductive circuit layer increases the current carrying capability of the conductive traces. The conductive circuit layer may provide other characteristics or benefits, such as environmental protection and a solderable surface for the conductive traces. Once plated, the conductive circuit layer and the conductive seed layer define conductive traces. Due to the electroplating process, when first plated, the conductive traces have circuit commons that common each of the circuits of the metal clad circuit board.

The method includes removing 210 sections of the conductive seed layer and sections of the conductive circuit layer during a circuit common removal process. Removal of such sections creates an electrical discontinuity at the circuit common area. The various circuits are no longer electrically commoned. Portions of the sacrificial bumps may be removed during the circuit common removal process.

Sections of the conductive seed layer and sections of the conductive circuit layer may be removed by a milling process. Alternatively, sections of the conductive seed layer and sections of the conductive circuit layer may be removed by another process such as a laser cutting process, a chemical etching process, an electro-machining process and the like. At least a portion of the sacrificial bump in the area between the discontinuity and the dielectric layer remains intact. The dielectric layer remains intact and/or untouched during the removal process.

The method includes applying 212 a solder mask over the conductive traces. The solder mask may be selectively applied over portions of the conductive traces, such as to protect the conductive traces from the environment. The solder mask controls the quality of the solder process by locating the solder to the appropriate areas. Portions of the conductive traces may be exposed by the solder mask to allow for soldering of electrical components to the conductive traces. For examples, LEDs or other electrical components may be soldered to the conductive traces. The solder mask may be applied using a printing process, such as a pad printing process or another application process.

Electrical components, such as LEDs or other electrical components are mounted 214 to the conductive traces of the conductive circuit layer. The electrical components may be mounted by soldering the electrical components to the conductive traces. The solder mask prevents soldering in unintended areas and prevents solder from flowing from the soldering areas.

Optionally, many metal clad circuit boards may be manufactured at one time as part of a panel. The method may include separating the individual metal clad circuit boards from one another. For example, the metal clad circuit boards may be routed or scored and broken from other metal clad circuit boards.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A method of manufacturing a circuit board comprising:
providing a metal substrate;
applying a dielectric layer to the metal substrate;
providing sacrificial bumps on the dielectric layer;
printing a conductive seed layer on the dielectric layer and the sacrificial bumps;
plating a conductive circuit layer onto the conductive seed layer; and
removing sections of the conductive seed layer and sections of the conductive circuit layer during a circuit common removal process.

2. The method of claim 1, further comprising removing portions of the sacrificial bumps during the circuit common removal process.

3. The method of claim 1, wherein said removing sections of the conductive seed layer and sections of the conductive circuit layer comprises milling the sections of the conductive seed layer and sections of the conductive circuit layer from the sacrificial bumps

4. The method of claim 1, wherein said removing sections of the conductive seed layer and sections of the conductive circuit layer comprises laser cutting the sections of the conductive seed layer and sections of the conductive circuit layer from the sacrificial bumps.

5. The method of claim 1, wherein said providing sacrificial bumps comprises printing dielectric material onto the dielectric layer.

6. The method of claim 1, wherein said providing sacrificial bumps on the dielectric layer comprises elevating the sacrificial bumps above an outer surface of the dielectric layer raising the conductive seed layer and the conductive circuit layer in the circuit common areas.

7. The method of claim 6, wherein said elevating the sacrificial bumps comprises elevating the sacrificial bumps to a selected thickness selected based on the removal method of the conductive circuit layer and the conductive seed layer such that the dielectric layer in the circuit common areas remains intact.

8. The method of claim 1, wherein said providing sacrificial bumps on the dielectric layer comprises providing the sacrificial bumps in a mound shape, the conductive seed layer and the conductive circuit layer transition from the dielectric layer to the sacrificial bumps such that the conductive seed layer and the conductive circuit layer are non-planar along the circuit board.

9. The method of claim 1, further comprising creating an electrical discontinuity at the circuit common areas by said removing sections of the conductive seed layer and conductive circuit layer.

10. The method of claim 1, further comprising creating an electrical discontinuity between remaining sections of the conductive circuit layer and the conductive seed layer that remain after the sections of the conductive circuit layer and the conductive seed layer are removed, wherein at least a portion of the sacrificial bump remains intact between the discontinuity and the dielectric layer in the circuit common areas.
